(19) United States
(12) Patent Application Publication
(10) Pub. No.: US 2015/0325516 A1
(43) Pub. Date: Nov. 12, 2015

(54) CORELESS PACKAGING SUBSTRATE, POP STRUCTURE, AND METHODS FOR FABRICATING THE SAME

(71) Applicant: Siliconware Precision Industries Co., Ltd., Taichung (TW)

(72) Inventors: Chun- Hsien Lin, Taichung (TW); Shih-Chao Chiu, Taichung (TW); Yu-cheng Pai, Taichung (TW); Tzu-Chieh Shen, Taichung (TW); Ming-Chen Sun, Taichung (TW)

(21) Appl. No.: 14/464,051

(22) Filed: Aug. 20, 2014

(30) Foreign Application Priority Data
May 9, 2014 (TW) 103116497

(51) Int. Cl. H01L 23/522; H01L 21/56; H01L 23/482; H01L 23/31; H01L 23/498; H01L 21/768

(52) U.S. Cl. CPC H01L 23/5226; H01L 23/49822; H01L 21/76897; H01L 23/4824; H01L 23/3157; H01L 21/56

(57) ABSTRACT

A method for fabricating a coreless packaging substrate is provided, which includes: forming a dielectric layer on a conductive plate having a plurality of conductive pads; forming a circuit layer on the dielectric layer and forming in the dielectric layer a plurality of conductive vias that electrically connect the circuit layer and the conductive pads; and removing a portion of the conductive plate so as to cause the remaining portion of the conductive plate to form a plurality of conductive elements, thereby dispensing with a core layer and reducing the material and fabrication cost.

### BACKGROUND OF THE INVENTION

1. Field of the Invention

The present invention relates to PoP (package on package) structures, and, more particularly, to a PoP structure with improved product yield and a method for fabricating the same.

2. Description of Related Art

Along with the progress of semiconductor packaging technologies, various package types have been developed for semiconductor devices. To improve electrical performances and save spaces, a plurality of packages can be stacked to form a package on package (PoP) structure. Such a packaging method allows merging of heterogeneous technologies in a system-in-package (SiP) so as to systematically integrate a plurality of electronic components having different functions, such as a memory, a CPU (Central Processing Unit), a GPU (Graphics Processing Unit), an image application processor and so on, and therefore is applicable to various thin type electronic products.

FIGS. 1A and 1B are schematic cross-sectional views of conventional PoP structures 1, 1′.

Referring to FIG. 1A, a first packaging substrate 11 and a second packaging substrate 12 are provided. The first packaging substrate 11 has a plurality of circuit layers 110, and the second packaging substrate 12 has a core layer 120 and plurality of circuit layers 121. A first semiconductor element 10 is disposed on the first packaging substrate 11 in a flip-chip manner and an underfill 14 is filled between the first semiconductor element 10 and the first packaging substrate 11. A plurality of second semiconductor elements 15 are disposed on the second packaging substrate 12 through wire bonding and an encapsulant 16 is formed on the second packaging substrate 12 to encapsulate the second semiconductor elements 15. Further, the second packaging substrate 12 and the first packaging substrate 11 are stacked and electrically connected through a plurality of solder balls 13.

Referring to FIG. 1B, a first packaging substrate 11 and a second packaging substrate 12 are provided. The first packaging substrate 11 has a plurality of circuit layers 110, and the second packaging substrate 12 has a core layer 120 and plurality of circuit layers 121. A first semiconductor element 10 is disposed on the first packaging substrate 11 in a flip-chip manner and an underfill 14 is filled between the first semiconductor element 10 and the first packaging substrate 11. Further, the second packaging substrate 12 and the first packaging substrate 11 are stacked and electrically connected through a plurality of solder balls 13. Furthermore, an encapsulant 16′ is formed to encapsulate the solder balls 13 and the first semiconductor element 10. In addition, a plurality of second semiconductor elements 15′ are disposed on the second packaging substrate 12 in a flip-chip manner.

However, in the PoP structures 1, 1′, the second packaging substrate 12 having a core layer incurs a high fabrication cost and cannot meet the thinning requirement.

Further, in the PoP structures 1, 1′, the solder balls 13 are used for mechanical support and electrically connection between the first packaging substrate 11 and the second packaging substrate 12. However, as I/O counts increase, if the size of the package does not change, the pitch between the solder balls 13 must be reduced. As such, solder bridging easily occurs between the solder balls 13, thus incurring a short circuit and reducing the product yield and reliability.

Furthermore, after a reflow process, the solder balls 13 may have large differences in volume and height from one another. That is, size variation of the solder balls 13 is not easy to control. As such, defects may occur to solder joints and result in a poor electrical connection quality. For example, during the reflow process, the solder balls 13 easily collapse and deform under pressure of the second packaging substrate 12. Therefore, solder bridging easily occurs between adjacent solder balls 13, thereby reducing the electrical connection quality. In addition, the solder balls 13 arranged in a grid array may have a poor coplanarity. Consequently, uneven stresses may be applied on the solder joints, thus easily leading to a tilted bonding between the two packaging substrates 11, 12 and even causing an offset of the solder joints.

Therefore, how to overcome the above-described drawbacks has become critical.

### SUMMARY OF THE INVENTION

In view of the above-described drawbacks, the present invention provides a coreless packaging substrate, which comprises: a dielectric layer having opposite first and second surfaces; a plurality of conductive pads embedded in the dielectric layer and exposed from the first surface of the dielectric layer; a plurality of conductive elements bonded to the conductive pads and protruding above the first surface of the dielectric layer, wherein the conductive elements are made of a non-solder material; a circuit layer formed on the second surface of the dielectric layer; and a plurality of conductive vias formed in the dielectric layer and electrically connecting the circuit layer and the conductive pads.

The present invention further provides a package on package (PoP) structure, which comprises the above-described coreless packaging substrate and at least a board connected to the conductive elements and stacked under the first surface of the dielectric layer of the coreless packaging substrate.

The present invention further provides a method for fabricating a coreless packaging substrate, which comprises the steps of: providing a conductive plate having a plurality of conductive pads formed on a surface thereof; forming a dielectric layer on the surface of the conductive plate, wherein the dielectric layer has a first surface bonded to the conductive plate and a second surface opposite to the first surface; forming a circuit layer on the second surface of the dielectric layer and forming in the dielectric layer a plurality of conductive vias that electrically connect the circuit layer and the conductive pads; and removing a portion of the conductive plate so as to cause the remaining portion of the conductive plate to form a plurality of conductive elements, wherein the conductive elements are bonded to the conductive pads and protruding above the first surface of the dielectric layer.

The present invention further provides a method for fabricating a PoP structure, which comprises the steps of fabricating a coreless packaging substrate having a plurality of conductive elements by using the above-described method, and connecting at least a board to the conductive elements so as to stack the board under the coreless packaging substrate.

In an embodiment, the conductive plate is a metal plate, and the conductive elements is made of a non-solder material. For example, the conductive elements are metal posts.

In an embodiment, the dielectric layer is formed on the conductive plate by laminating.

In an embodiment, each of the conductive pads has a surface flush with the first surface of the dielectric layer.

In an embodiment, the board is a circuit board having a core layer or a coreless circuit board.

In an embodiment, the board is connected to the conductive elements through a plurality of support members; the support members is made of copper or a solder material; and after the board is stacked under the coreless packaging substrate, an encapsulant is formed for encapsulating the support members and the conductive elements. Alternatively, before the board is stacked under the coreless packaging substrate, an encapsulant can be formed on the board and the support members are exposed from the encapsulant.

In an embodiment, at least an electronic component is disposed on the board.

In an embodiment, an encapsulant is formed between the coreless packaging substrate and the board.

In an embodiment, at least an electronic component is disposed on the circuit layer.

According to the present invention, a coreless circuit structure is formed on a conductive plate and then the conductive plate is processed to form a plurality of conductive elements, thus dispensing with a core layer and reducing the material and fabrication cost.

Further, by stacking the board and the packaging substrate through the conductive elements, the present invention reduces the use of a solder material, thereby preventing bridging from occurring and hence meeting the fine pitch requirement and increasing the product yield.

### BRIEF DESCRIPTION OF DRAWINGS

FIGS. 1A and 1B are schematic cross-sectional views of conventional PoP structures;

FIGS. 2A to 2H are schematic cross-sectional views showing a method for fabricating a coreless packaging substrate according to the present invention; and

FIGS. 3A to 3C are schematic cross-sectional views showing different embodiments of a PoP structure of the present invention, wherein FIG. 3A′ shows another embodiment of FIG. 3A.

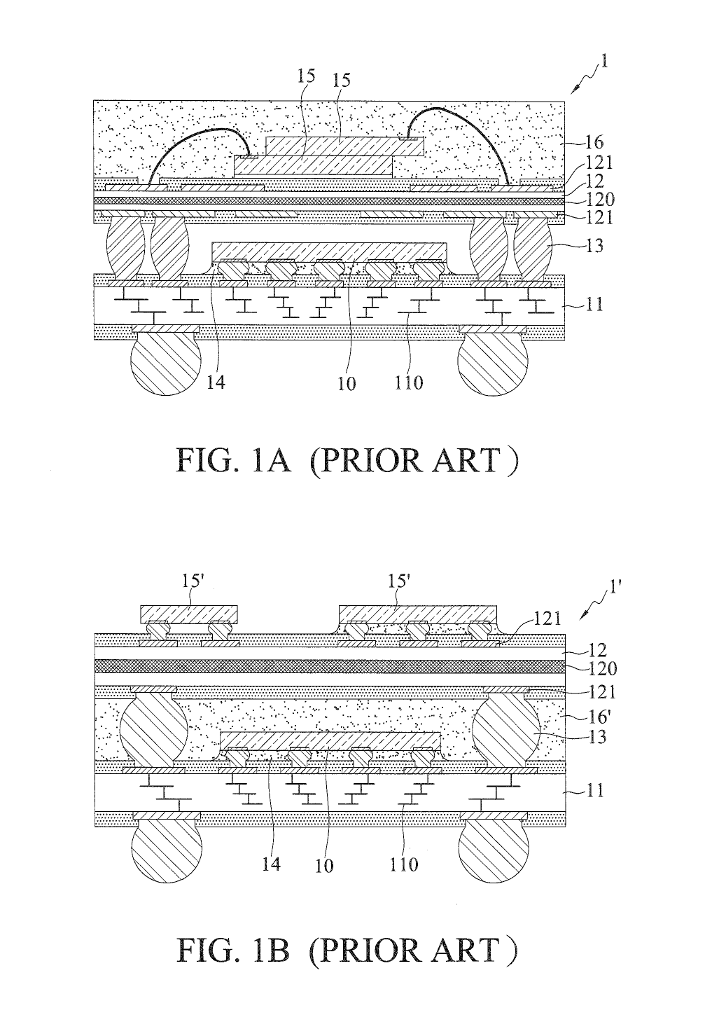

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “on”, “a” etc. are merely for illustrative purposes and should not be construed to limit the scope of the present invention.

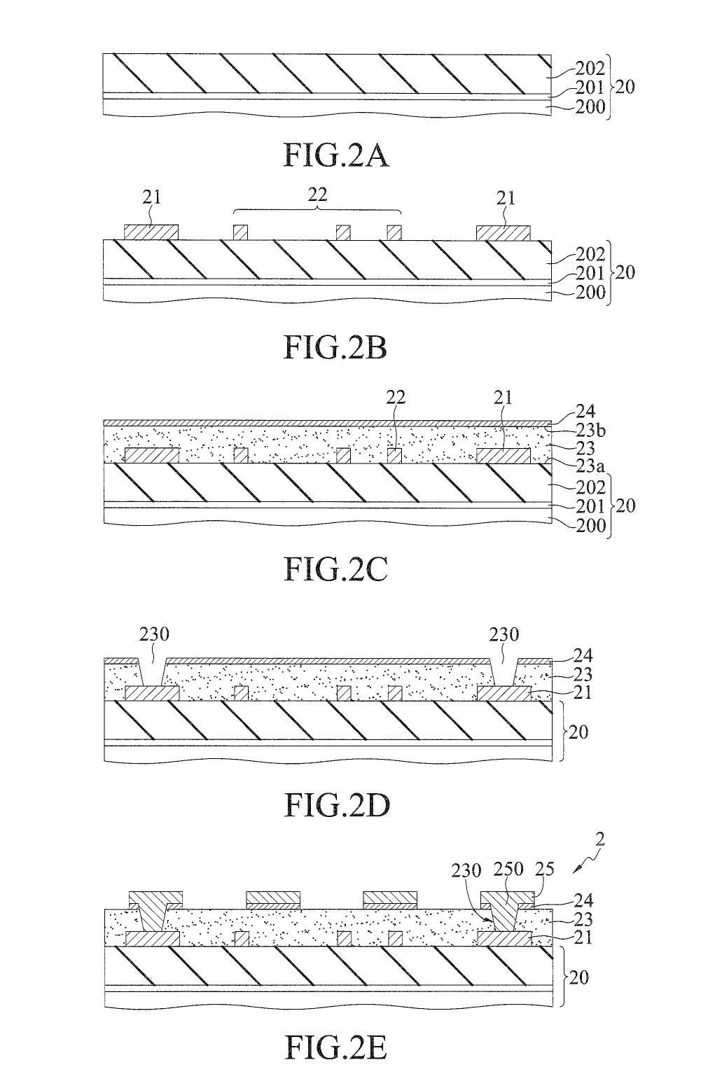

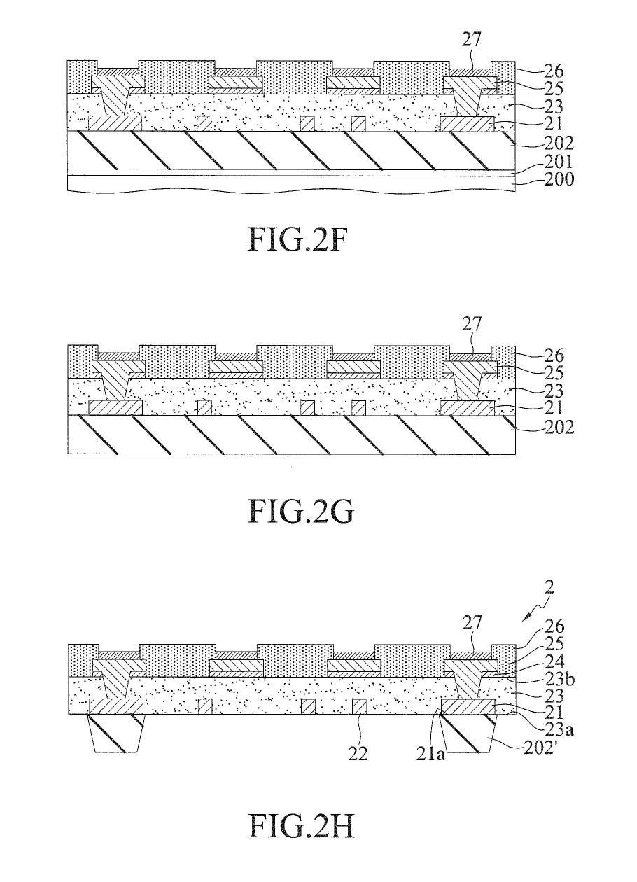

FIGS. 2A to 2H are schematic cross-sectional views showing a method for fabricating a coreless packaging substrate 2 according to a first embodiment of the present invention.

Referring to FIG. 2A, a carrier 20 is provided. The carrier 20 has a substrate 200, a release layer 201 formed on the substrate 200, and a conductive plate 202 disposed on the release layer 201.

In an embodiment, the conductive plate 202 is a metal plate such as a copper plate.

Referring to FIG. 2B, a plurality of conductive pads 21 and circuits 22 are formed on the conductive plate 202.

Referring to FIG. 2C, a dielectric layer 23 is formed on the conductive plate 202.

In an embodiment, the dielectric layer 23 has a first surface 23a bonded to the conductive plate 202, and a second surface 23b opposite to the first surface 23a. A conductive layer 24 made of metal such as copper is formed on the second surface 23b of the dielectric layer 23.

The dielectric layer 23 is made of prepreg, and formed on the conductive plate 202 by laminating.

Referring to FIG. 2D, a plurality of through holes 230 are formed by laser drilling to penetrate the dielectric layer 23 and the conductive layer 24 corresponding in position to the conductive pads 21.

Referring to FIG. 2E, with the conductive layer 24 used as a seed layer, an electroplating process is performed to form a circuit layer 25 on the dielectric layer 23 and form conductive vias 250 in the through holes 230 for electrically connecting the circuit layer 25 and the conductive pads 21.

Referring to FIG. 2F, an insulating layer 26 is formed on the dielectric layer 23 and the circuit layer 25 and portions of the circuit layer 25 are exposed from the insulating layer 26 for mounting an external element.

In an embodiment, a surface finish layer 27 is formed on the exposed portions of the circuit layer 25.

Referring to FIG. 20, the substrate 200 is removed from the conductive plate 202 through the release layer 201.

Referring to FIG. 2H, the conductive plate 202 is patterned and partially removed by etching so as to form a plurality of conductive elements 202′. As such, a coreless packaging substrate 2 is formed. The conductive elements 202′ are bonded to surfaces 21a of the conductive pads 21 and protrude above the first surface 23a of the dielectric layer 23.

In an embodiment, the surfaces 21a of the conductive pads 21 are flush with the first surface 23a of the dielectric layer 23 and the circuits 22 are exposed from the first surface 23a of the dielectric layer 23.

Further, since the conductive plate 202 is made of a non-solder material, the conductive elements 202′ are made of a non-solder material. In an embodiment, the conductive elements 202′ are metal posts such as copper posts.

In addition, the conductive elements 202′ have a tapered shape from bottom to top.

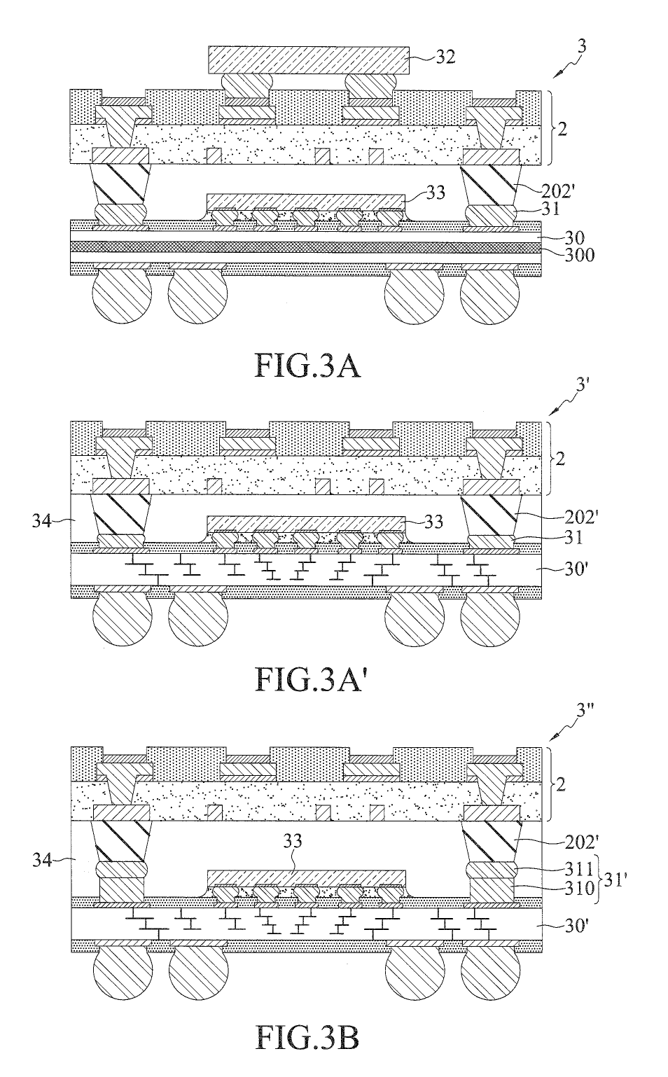

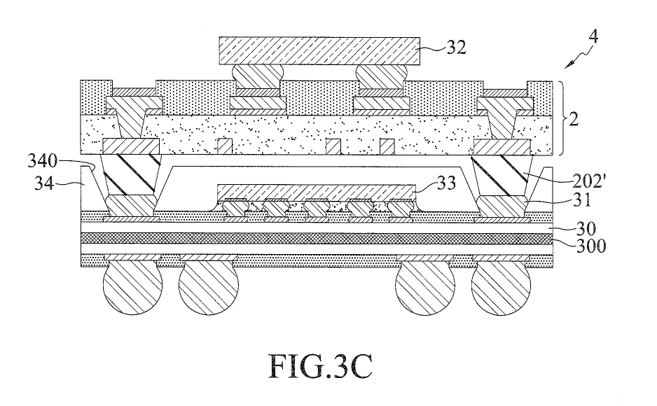

Referring to FIG. 3A, subsequently, a board 30 is connected to the conductive elements 202′ so as to be stacked under the coreless packaging substrate 2, thereby forming a PoP (Package on Package) structure 3.

In an embodiment, the board 30 is a circuit board having a core layer 300. Referring to FIG. 3A′, in another embodiment the board 30′ is a coreless circuit board.

Further, the board 30, 30′ is connected to the conductive elements 202′ through a plurality of support members 31. The support members 31 are made of a solder material. In another embodiment, referring to FIG. 3B, each of the support members 31′ has a copper post 310 and a solder material 311 formed on the copper post 310.

At least an electronic component 32 is disposed on the circuit layer 25 of the coreless packaging substrate 2. Further, an electronic component 33 is selectively disposed on the board 30. In an embodiment, the electronic component 32, 33 can be an active component, such as a chip, or a passive component, such as a resistor, a capacitor or an inductor.

Referring to FIGS. 3A′ and 3B, after the stacking process, an encapsulant 34 is formed between the coreless packaging substrate 2 and the board 30′ to encapsulate the conductive elements 202′, the support members 31, 31′ and the electronic component 33. Alternatively, referring to FIG. 3C, an encapsulant 34 is formed on the board 30 first and then a plurality of openings 340 are formed in the encapsulant 34 to expose the support members 31. Thereafter, the coreless packaging substrate 2 is disposed on the support members 31 through the conductive elements 202′.

According to the present invention, a coreless circuit structure is formed on the conductive plate 202 and then the conductive plate 202 is processed to form a plurality of conductive elements 202′, thus dispensing with a core layer and reducing the material and fabrication cost.

Further, by stacking the board 30, 30′ and the packaging substrate 2 through the conductive elements 202′, the present invention reduces the use of a solder material, thereby preventing bridging from occurring and hence meeting the fine pitch requirement and increasing the product yield.

Furthermore, the conductive elements 202′ have small differences in volume and height from one another during a reflow process. That is, size variation of the conductive elements 202′ is easy to control. Therefore, good joints can be formed between the coreless packaging substrate 2 and the board 30, 30′, thereby improving the electrical connection quality. Further, the conductive elements 202′ arranged in a grid array has a good coplanarity. Hence, the present invention can easily control the height of the product and also prevents a tilted bonding between the packaging substrate 2 and the board 30, 30′.

The present invention further provides a coreless packaging substrate 2, which has: a dielectric layer 23 having opposite first and second surfaces 23a, 23b; a plurality of conductive pads 21 embedded in the dielectric layer 23 and exposed from the first surface 23a of the dielectric layer 23; a plurality of conductive elements 202′ bonded to the conductive pads 21 and protruding above the first surface 23a of the dielectric layer 23, wherein the conductive elements 202′ are made of a non-solder material; a circuit layer 25 formed on the second surface 23b of the dielectric layer 23; and a plurality of conductive vias 250 formed in the dielectric layer 23 and electrically connecting the circuit layer 25 and the conductive pads 21.

In an embodiment, each of the conductive pads 21 has a surface 21a flush with the first surface 23a of the dielectric layer 23.

In an embodiment, the conductive elements 202′ are metal posts.

The present invention further provides a PoP structure 3, 3′, 3″, 4, which has: the coreless packaging substrate 2, and a board 30, 30′ connected to the conductive elements 202′ and stacked under the first surface 23a of the dielectric layer 23 of the coreless packaging substrate 2.

In an embodiment, the board 30, 30′ is a circuit board having a core layer 300 or a coreless circuit board.

In an embodiment, the board 30, 30′ is connected to the conductive elements 202′ through a plurality of support members 31, 31′.

In an embodiment, the support members 31, 31′ are made of copper or a solder material.

In an embodiment, at least an electronic component 33 is disposed on the board 30, 30′. Further, an encapsulant 34 is formed and encapsulating the support members 31, 31′ and the electronic component 33.

In an embodiment, the PoP structure 3, 4 further has at least an electronic component 32 disposed on the circuit layer 25.

Therefore, the packaging substrate according to the present invention dispenses with a core layer so as to reduce the material and fabrication cost.

Further, the conductive elements facilitate to reduce the use of a solder material so as to meet the fine pitch requirement and increase the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A coreless packaging substrate, comprising:
a dielectric layer having opposite first and second surfaces;
a plurality of conductive pads embedded in the dielectric layer and exposed from the first surface of the dielectric layer;
a plurality of conductive elements bonded to the conductive pads and protruding above the first surface of the dielectric layer, wherein the conductive elements are made of a non-solder material;
a circuit layer formed on the second surface of the dielectric layer; and
a plurality of conductive vias formed in the dielectric layer and electrically connecting the circuit layer and the conductive pads.

2. The coreless packaging substrate of claim 1, wherein the conductive elements are metal posts.

3. The coreless packaging substrate of claim 1, wherein each of the conductive pads has a surface flush with the first surface of the dielectric layer.

4. A package on package structure, comprising:
a coreless packaging substrate, comprising:
a dielectric layer having opposite first and second surfaces;
a plurality of conductive pads embedded in the dielectric layer and exposed from the first surface of the dielectric layer;
a plurality of conductive elements bonded to the conductive pads and protruding above the first surface of the dielectric layer, wherein the conductive elements are made of a non-solder material;
a circuit layer formed on the second surface of the dielectric layer; and
a plurality of conductive vias formed in the dielectric layer and electrically connecting the circuit layer and the conductive pads; and
at least a board connected to the conductive elements and stacked under the coreless packaging substrate.

5. The package on package structure of claim 4, wherein the conductive elements are metal posts.

6. The package on package structure of claim 4, wherein each of the conductive pads has a surface flush with the first surface of the dielectric layer.

7. The package on package structure of claim 4, wherein the board is a circuit board having a core layer or a coreless circuit board.

8. The package on package structure of claim 4, wherein the board is connected to the conductive elements through a plurality of support members.

9. The package on package structure of claim 8, wherein the support members are made of copper or a solder material.

10. The package on package structure of claim 8, further comprising an encapsulant encapsulating the support members.

11. The package on package structure of claim 4, wherein at least an electronic component is disposed on the board.

12. The package on package structure of claim 4, further comprising an encapsulant formed between the coreless packaging substrate and the board.

13. The package on package structure of claim 4, further comprising at least an electronic component disposed on the circuit layer.

14. A method for fabricating a coreless packaging substrate, comprising the steps of:
providing a conductive plate having a plurality of conductive pads formed on a surface thereof;
forming a dielectric layer on the surface of the conductive plate, wherein the dielectric layer has a first surface bonded to the conductive plate and a second surface opposite to the first surface;
forming a circuit layer on the second surface of the dielectric layer and forming in the dielectric layer a plurality of conductive vias that electrically connect the circuit layer and the conductive pads; and
removing a portion of the conductive plate so as to cause the remaining portion of the conductive plate to form a plurality of conductive elements, wherein the conductive elements are bonded to the conductive pads and protrude above the first surface of the dielectric layer.

15. The method of claim 14, wherein the conductive plate is a metal plate.

16. The method of claim 14, wherein the conductive elements are made of a non-solder material.

17. The method of claim 14, wherein the dielectric layer is formed on the conductive plate by laminating.

18. A method for fabricating a package on package structure, comprising the steps of:
providing a coreless packaging substrate having a plurality of conductive elements; and
connecting at least a board to the conductive elements so as to stack the board under the coreless packaging substrate.

19. The method of claim 18, wherein the conductive elements are made of a non-solder material.

20. The method of claim 18, wherein the coreless packaging substrate is fabricated by:
providing a conductive plate having a plurality of conductive pads on a surface thereof;
forming on the surface of the conductive plate a dielectric layer that has a first surface bonded to the conductive plate and a second surface opposite to the first surface;
forming a circuit layer on the second surface of the dielectric layer and forming in the dielectric layer a plurality of conductive vias that electrically connect the circuit layer and the conductive pads; and
removing a portion of the conductive plate so as to cause the remaining portion of the conductive plate to form a plurality of conductive elements, wherein the conductive elements are bonded to the conductive pads and protrude above the first surface of the dielectric layer.

21. The method of claim 20, wherein the conductive plate is a metal plate.

22. The method of claim 20, wherein each of the conductive pads has a surface flush with the first surface of the dielectric layer.

23. The method of claim 20, further comprising disposing at least an electronic component on the circuit layer.

24. The method of claim 18, wherein the board is a circuit board having a core layer or a coreless circuit board.

25. The method of claim 18, wherein the board is connected to the conductive elements through a plurality of support members.

26. The method of claim 25, wherein the support members are made of copper or a solder material.

27. The method of claim 25, after stacking the board under the coreless packaging substrate, further comprising forming an encapsulant for encapsulating the support members.

28. The method of claim 25, before stacking the board under the coreless packaging substrate, further comprising forming an encapsulant on the board, wherein the support members are exposed from the encapsulant.

29. The method of claim 18, wherein at least an electronic component is disposed on the board.

30. The method of claim 18, further comprising forming an encapsulant between the coreless packaging substrate and the board.
